(19) United States
(12) Patent Application Publication
(10) Pub. No.: US 2006/0005761 A1
(43) Pub. Date: Jan. 12, 2006

(54) Method and apparatus for growing silicon crystal by controlling melt-solid interface shape as a function of axial length

(75) Inventors: Milind Kulkarni, St. Louis, MO (US); Vijay Nithiananthan, St. Charles, MO (US); Lee W. Ferry, St. Charles, MO (US); JaeWoo Ryu, Chonan (KR); JinYong Uhm, Plano, TX (US); Steven L. Kimbel, St. Charles, MO (US); ChangBum Kim, Chesterfield, MO (US); Joseph C. Holzer, St. Charles, MO (US); Richard G. Schrenker, St. Louis, MO (US); KangSeon Lee, Chonan (KR)

Correspondence Address: SENNIGER POWERS, ONE METROPOLITAN SQUARE, 16TH FLOOR, ST LOUIS, MO, 63102, US

(73) Assignee: MEMC Electronic Materials, Inc., St. Peters, MO (US)

(21) Appl. No.: 11/145,626

(22) Filed: Jun. 6, 2005

Related U.S. Application Data
(60) Provisional application No. 60/577,722, filed on Jun. 7, 2004.

(51) Int. Cl. C30B 15/00; C30B 15/30; C30B 21/06; C30B 27/02

(52) U.S. Cl. 117/15; 117/13; 117/14; 117/202; 117/213

(57) ABSTRACT

The present invention provides a methods and system for producing semiconductor grade single crystals that are substantially free of undesirable agglomerated defects. A vacancy/interstial (V/I) boundary simulator analyzes various melt-solid interface shapes to predict a corresponding V/I transition curve for each of the various melt-solid interface shapes. A target melt-solid interface shape corresponding to a substantially flat V/I curve is identified for each of a plurality of axial positions along the length of the crystal. Target operating parameters to achieve each of the identified melt-solid interface shapes are stored in a melt-solid interfaced shape profile. A control system is responsive to the stored profile to generate one or more control signals to control one or more output devices such that the melt-solid interfaced shape substantially follows the target shapes as defined by the profile during crystal growth.

### CROSS REFERENCE TO RELATED APPLICATIONS

This application in claims priority from U.S. Provisional Application No. 60/577,722, filed on Jun. 7, 2004.

### FIELD OF THE INVENTION

The present invention generally relates to producing semiconductor grade single crystal silicon that can be used in the manufacture of electronic components and the like. More particularly, the present invention relates to processes for producing silicon ingots by controlling the shape of the melt-solid interface in a selected thermal environment.

### BACKGROUND OF THE INVENTION

Single crystal silicon, which is the starting material for most processes for the fabrication of semiconductor electronic components, is commonly prepared by the so-called Czochralski (“Cz”) method. In this method, polycrystalline silicon (“polysilicon”) is charged to a crucible and melted, a seed crystal is brought into contact with the molten silicon and a single crystal is grown by slow extraction. Silicon crystals grown from a melt may be grown with an excess of one or the other type of intrinsic point defect, either crystal lattice vacancies (“V”) or silicon self-interstitials (“I”) and may have regions of both or of neither. It has been suggested that the dominant point defect type is determined near solidification and, if the dominant-point defect concentrations reach a level of critical supersaturation in the system and the mobility of the point defects is sufficiently high, a reaction, or an agglomeration event, will likely occur. Agglomerated intrinsic point defects in silicon can severely impact the yield potential of the material in the production of complex and highly integrated circuits.

Those skilled in the art are familiar with the ratio of the pull rate v of the crystal to an axial thermal gradient G being indicative of the type of intrinsic point defect likely to occur in the growing crystal. For example, when the pull rate is high lattice vacancies are the dominant point defects. Alternatively, when pull rate is low silicon self-interstitials are the dominant point defects. Thus, during a dynamic growth process (i.e., where v/G may vary as a function of the radius and/or axial length of the crystal) point defects within the growing silicon crystal can change from being vacancy dominated to interstitial dominated, or vice versa. Moreover, there is an identifiable vacancies/self-interstitials (V/I) transition associated with such a change.

### SUMMARY OF THE INVENTION

In accordance with the present invention, it has been discovered that substantially defect-free single silicon crystals can be produced by closely controlling the shape of the molten silicon/silicon crystal (melt/crystal or melt-solid) interface. In particular, by controlling the melt-solid interface shape according to a target melt-solid shape profile as a function of axial length, a region substantially free of agglomerated defects may be produced. Further, by selecting a smooth seed lift profile that is determined using the V/I transition pull rate values, perfect silicon material may be produced over substantially all of the crystal body length. The target interface shape is unique to the crystal hotzone design and position along the axial length of the ingot.

In accordance with one aspect of the invention, a method for use in combination with a crystal growing apparatus for growing a monocrystalline ingot according to the Czochralski process is provided. The crystal growing apparatus includes a heated crucible containing a semiconductor melt from which the ingot is pulled. The ingot is grown on a seed crystal pulled from the melt. The method includes determining a set point for an operating parameter of the crystal growing apparatus as a function of a length of the ingot during pulling. The set point is specified by a pre-defined melt-solid interface shape profile that represents a desired shape of a melt-solid interface between the melt and the ingot during pulling as a function of the length of the ingot and an operating condition affecting the melt. The method also includes adjusting the operating condition of the crystal growing apparatus according to the determined operating parameter set point to control the shape of the melt-solid interface while the ingot is being pulled from the melt.

In accordance with another aspect of the invention, a method for defining a melt-solid interface shape profile is provided. The profile is used in combination with a crystal growing apparatus for growing a monocrystalline ingot according to the Czochralski process. The crystal growing apparatus includes a heated crucible containing a semiconductor melt from which the ingot is pulled. The ingot is grown on a seed crystal pulled from the melt. The melt-solid interface shape profile represents a desired shape of a melt-solid interface between the melt and the ingot during pulling as a function of the length of the ingot. The method includes selecting a plurality of axial positions along the length of a model ingot and defining a plurality of melt-solid interface shapes for each of the identified axial positions. The method also includes determining a thermal model of a hotzone of the crystal growing apparatus for each of the axial positions and each of the melt-solid interface shapes. The method also includes defining a velocity profile representative of a ramped pull rate. The method also includes determining point defects concentration fields in all regions of interest of the model ingot using a point defect simulator. The point defect model is responsive to the velocity profile and the thermal model for identifying a V/I transition for each of the plurality of defined melt solid interface shapes for each of the plurality of identified axial positions. The method further includes identifying a target melt-solid interface shape corresponding to a substantially flat V/I transition for each of the plurality of identified axial positions.

In accordance with yet another aspect of the invention, a system for use in combination with a crystal growing apparatus for growing a monocrystalline ingot according to the Czochralski process is provided. The crystal growing apparatus includes a heated crucible containing a semiconductor melt from which the ingot is pulled. The ingot is grown on a seed crystal pulled from the melt. The apparatus includes a memory storing a pre-defined melt-solid interface profile. The melt-solid interface profile represents a desired shape of a melt solid interface between the melt and the ingot during pulling as a function of a length of the ingot and an operating condition affecting the melt. A processor is responsive to the pre-defined melt-solid interface profile for determining a set point for an operating parameter of the crystal growing apparatus as a function of the length of the ingot during pulling. A controller is responsive to the determined operating parameter set point to adjust the operation condition of the crystal growing apparatus according to the determined operating parameter set point to control the shape of the melt-solid interface while the ingot is being pulled from the melt.

Alternatively, the invention may comprise various other methods and apparatuses.

Other features will be in part apparent and in part pointed out hereinafter.

### BRIEF DESCRIPTION OF THE DRAWINGS

FIG. 1 is an illustration of a crystal growing apparatus and an apparatus according to an embodiment of the present invention for controlling the crystal growing apparatus.

FIG. 2 illustrates an exemplary growing single silicon crystal 31 having a concave melt-solid interface shape relative to the crystal.

FIG. 3A illustrates modeling components of a V/I simulator for generating an expected V/I transition according to an embodiment of the invention.

FIG. 3B illustrates various exemplary molten silicon/silicon crystal interface shapes for analyses by the V/I simulator of FIG. 3.

FIG. 3C illustrates a vertical component and a horizontal component corresponding to one data point of a series of data points defining an exemplary assumed molten silicon/silicon crystal interface shape.

FIG. 3D illustrates an exemplary velocity profile for pulling single crystal silicon ingot 31 to force a V/I transition during a simulated growth process.

FIG. 3E illustrates an exemplary V/I transition plot generated by the V/I simulator in response to an assumed melt-solid interface shape.

FIG. 4A illustrates various melt-solid interface shapes corresponding to an exemplary melt-solid interface shape profile for growing a single crystal silicon ingot.

FIG. 4B illustrates a cropped vertical section of an ingot subjected to a precipitation thermal cycle for measuring the melt interface shapes at various axial positions.

FIG. 5A illustrates components of the control system for controlling the melt-solid interface shape of a crystal according to one preferred embodiment of the invention.

FIG. 5B is an exemplary graph illustrating changes in melt-solid interface shape as function of changes in crucible surface temperature being supplied from a bottom heater, or by a change in lower insulation.

FIG. 5C is an exemplary graph illustrating changes in melt-solid interface shape as function of changes in the magnet field being applied by a magnet.

FIG. 5D is an exemplary graph illustrating changes in melt-solid interface shape as function of a rotation speed differential between the crucible and the crystal.

FIG. 5E is an exemplary graph illustrating the increased range over which the interface shapes can be controlled during an iso-rotation process.

FIG. 6 is an exemplary flow chart illustrating a method for defining a melt-solid interface shape profile for use in combination with a crystal growing apparatus when growing a monocrystalline ingot according to the Czochralski process according to one embodiment of the invention.

FIG. 7 is an exemplary graph illustrating measured interface shapes of a crystal and a point defect concentration field generated by a point defect simulator as a function of the measured interface shapes.

Corresponding reference characters indicate corresponding parts throughout the several views of the drawings.

### DETAILED DESCRIPTION OF THE INVENTION

Single crystal silicon, which is the starting material for most processes for the fabrication of semiconductor electronic components, is commonly prepared by the so-called Czochralski (“Cz”) method. In this method, polycrystalline silicon (“polysilicon”) is charged to a crucible and melted, a seed crystal is brought into contact with the molten silicon and a single crystal is grown by slow extraction. The present invention proposes a method and system for producing silicon crystal ingots suitable for use in device manufacturing. In some embodiments, the method and system of the present invention may be used to produce a silicon crystal ingot, a substantial portion or all of which is substantially free of agglomerated intrinsic point defects. That is, silicon ingots, a substantial portion or all of which is has a density of detectable defects of less than about 1×10⁴ defects/cm³, less than about 5×10³ defects/cm³, less than about 1×10³ defects/cm³ or even no detectable agglomerated intrinsic point defects). In other embodiments, the present invention may produce silicon ingots having substantially no agglomerated defects that are larger than about 60 nm in diameter.) More specifically, the present invention can control the shape of the molten silicon and crystal (melt-solid) interface during crystal growth to limit and/or suppress the formation of agglomerated intrinsic point defects. The melt-solid interface shape may be concave, convex in shape relative to the crystal, and may even be both concave and convex in shape relative to the crystal (e.g., a “sea gull wing” shape). It has been discovered that the melt-solid interface shape is an important parameter for controlling defects during crystal growth.

The shape of melt-solid interface can be affected significantly by melt convection. Convection refers to the process of heat transfer in a liquid by the movement of the liquid itself. In general, there are two types of convection: natural convention and forced convection. Natural convection is when the movement of the melt is due, for example, solely to the presence of heaters giving rise to density gradients. Forced convection is when the movement of the melt is due to an external agent such as magnetic fields in the crucible, or rotational speed and or direction of the ingot and/or crucible. Accordingly, the shape of the melt-solid interface may be controlled by controlling one or more of at least four (4) operational parameters, which can be used alone, or in combination, to achieve the desired shape of melt-solid interface shape. These parameters include (1) heat flux, which determines the melt boundary temperature field, generated by either a change in lower heater power or by a change in lower insulation level or efficiency (e.g., adjust bottom heater output); (2) magnetic field strength; (3) rotation of the crucible; and (4) rotation of the silicon crystal.

For instance, because magnetic fields can affect the flow pattern in electrically conducting fluids such as silicon melt, a magnet (e.g., Cusp type, Vertical type and Horizontal type) can be used to affect melt convection, and, thus change the temperature distribution in the melt, which, in turn, can affect on the melt-solid interface shape. Similarly, crucible and crystal rotation influences the flow pattern in of the, and, thus, affect the temperature distribution in the melt, which, again, affects the melt-solid interface shape. Conventionally, the crucible and crystal are rotated in opposite directions when growing a silicon single crystal. This process is referred to herein as counter-rotation. Although controlling the difference between the rotational rate of the crucible and the rotational rate crystal in a counter rotation process may be used to affect on the shape the melt-solid interface, it has been discovered by the inventors that a so-called iso-rotation process provides for greater control of the melt-solid interface shape. In an iso-rotation process, both the crucible and crystal (i.e., seed) are rotated in the same direction and the difference between the rotational rate of the crucible and the rotational rate crystal may be used to affect on the shape the melt-solid interface.

Silicon crystals grown from a melt may be grown with an excess of one or the other type of intrinsic point defect, either crystal lattice vacancies (“V”) or silicon self-interstitials (“I”) and may have regions of both or of neither. According to one or more embodiments of the present invention, the crystal/melt interface shape may be controlled during the growth of the crystal to control the initial distribution of point defects at solidification front at several degrees or tens of degrees (around 100 degrees) from the melt-solid interface. It has been suggested that the dominant point defect type is determined near solidification and, if the dominant-point defect concentrations reach a level of critical supersaturation in the system and the mobility of the point defects is sufficiently high, a reaction, or an agglomeration event, will likely occur. Agglomerated intrinsic point defects in silicon can severely impact the yield potential of the material in the production of complex and highly integrated circuits. By controlling the shape of the melt-solid interface, the agglomeration reaction may be greatly reduced and even avoided entirely, producing silicon substantially free of agglomerated intrinsic point defects.

Those skilled in the art are familiar with the ratio of the pull rate v of the crystal to an axial thermal gradient G being indicative of the type of intrinsic point defect likely to occur in the growing crystal. For example, when the pull rate is high lattice vacancies are the dominant point defects. Alternatively, when pull rate is low silicon self-interstitials are the dominant point defects. Thus, during a dynamic growth process (i.e., where v/G may vary as a function of the radius and/or axial length of the crystal) point defects within the growing silicon crystal can change from being vacancy dominated to interstitial dominated, or vice versa. Moreover, there is an identifiable vacancies/self-interstitials (V/I) transition associated with such a change. It has been discovered that a large-defect free region exists between agglomerated vacancy defects and agglomerated interstitial type defects. Significantly, the V/I transition occurs within this defect-free region. That is, this defect free region corresponds to the transition region from an excess vacancy dominant region to an excess interstitial dominant region. The defect-free region may be vacancy dominated and/or interstitial dominated material. The defect-free region does not contain critical excess point defects to form any defects and generally includes the V/I transition.

Moreover, it has been discovered that when the identified V/I transition has a preferred shape, or profile, the crystal is substantially free of agglomerated defects at this transition. For instance, a substantially flat V/I transition perpendicular to the pull axis under dynamic growth simulations corresponds to a portion of the crystal substantially free of agglomerated defects.

According to the present invention, a target interface shape is determined for a particular hotzone at various positions along the length of the crystal to determine the target interface shape profile for the given hotzone. By suppressing or otherwise controlling the agglomeration reactions that produce agglomerated defects, rather than simply limiting the rate at which such defects form, or attempting to annihilate some of the defects after they have formed, a method acting to suppress or control agglomeration reactions yields a silicon substrate that is substantially free of undesirable amounts or sizes of agglomerated intrinsic point defects. Such a method also affords single crystal silicon wafers having epi-like yield potential, in terms of the number of integrated circuits obtained per wafer, without having the high costs associated with an epitaxial process.

According to one embodiment of the invention, the melt-solid interface shape is controlled within a certain range or percentage of a height deviation ratio (HDR). For example, the molten silicon is controlled for a 200 mm crystal such that the height deviation ratio (HDR) ratio between crystal center and edge is about plus or minus about 11%, preferably about plus or minus about 9%, more preferably plus or minus about 7%, and most preferably plus or minus about 5%. Where the height deviation ratio is determined from the following equation:
HDR=[Hc−He]/Radius×100, (1);
where Hc is height of crystal center from melt surface and He is height of crystal edge from melt surface. For crystals having a diameter other than 200 mm, the maximum height deviation ratio is gradually decreased by a slope of 0.06 by the crystal radius. In another embodiment, an acceptable range or operating window is determined as described in APPENDIX A.

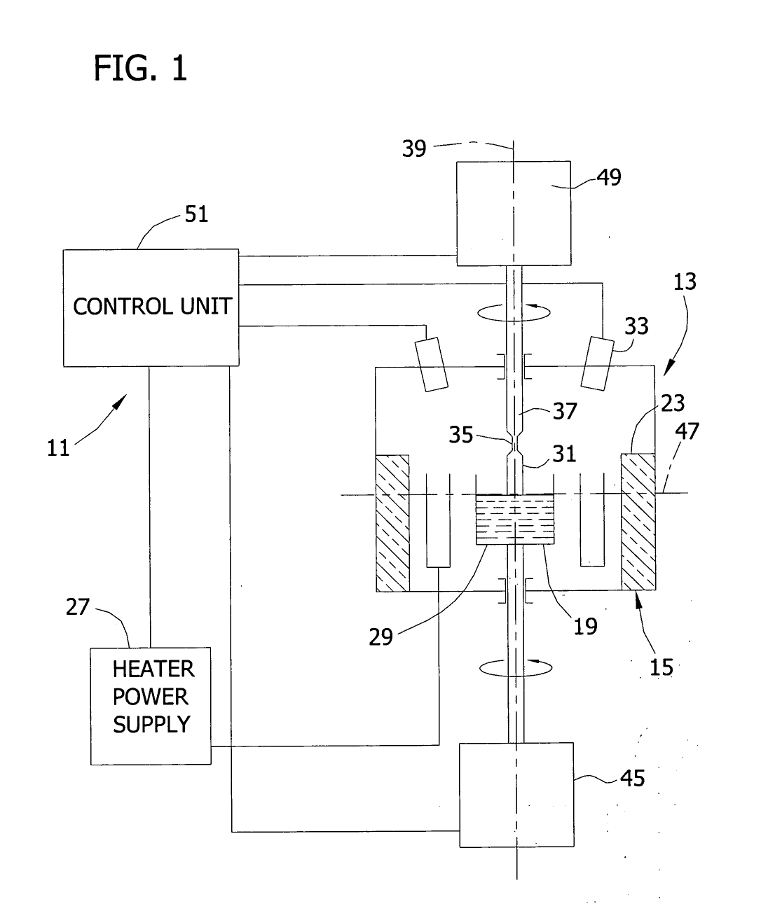

Referring now to FIG. 1, a system, indicated generally at 11, is shown for use with a Czochralski crystal growing apparatus, indicated generally at 13. In general, crystal growing apparatus 13 includes a vacuum chamber 15 enclosing a crucible 19. Heating means such as a resistance heater 21 surrounds the crucible 19. In one embodiment, insulation 23 lines the inner wall of vacuum chamber 15 and a chamber cooling jacket (not shown) fed with water surrounds it. A vacuum pump (not shown) typically removes gas from within the vacuum chamber 15 as an inert atmosphere of argon gas is fed into it. According to the Czochralski single crystal growth process, a quantity of polycrystalline silicon, or polysilicon, is charged to crucible 19. A heater power supply 27 provides electric current through the resistance heater 21 to melt the charge and, thus, form a silicon melt 29 from which a single crystal 31 is pulled. Typically, a temperature sensor 33, such as a photocell or pyrometer, is to be used to provide measurements of the melt surface temperature. The single crystal 31 starts with a seed crystal 35 attached to a pull shaft, or cable, 37. As shown in FIG. 1, single crystal 31 and crucible 19 generally have a common axis of symmetry 39. One end of cable 37 is connected by way of a pulley (not shown) to a drum (not shown) and the other end is connected to a chuck (not shown) that holds the seed crystal 35 and the crystal 31 grown from the seed crystal.

During both heating and crystal pulling, a crucible drive unit (i.e., motor) 45 rotates crucible 19 (e.g., in the clockwise direction). The crucible drive unit 45 may also raise and/or lower the crucible 19 as desired during the growth process. For example, crucible drive unit 45 raises crucible 19 as the melt 29 is depleted to maintain its level, indicated by reference character 47, at a desired height. A crystal drive unit 49 similarly rotates the cable 37 in a direction opposite the direction in which crucible drive unit 45 rotates crucible 19 (e.g., in the counter-clockwise direction) or in the same direction as the crucible drive (e.g., iso-rotation). In embodiments using iso-rotation, the crystal drive unit 49 may rotate the cable 37 in the same direction in which crucible drive unit 45 rotates crucible 19 (e.g., in the clockwise direction) In addition, the crystal drive unit 49 raises and lowers crystal 31 relative to the melt level 47 as desired during the growth process.

In one embodiment, crystal growth apparatus 13 preheats the seed crystal 35 by lowering it nearly into contact with the molten silicon of melt 29 contained by crucible 19. After preheating, crystal drive unit 49 continues to lower seed crystal 35 via cable 37 into contact with melt 29 at its melt level 47. As seed crystal 35 melts, crystal drive unit 49 slowly withdraws, or pulls, it from the melt 29. Seed crystal 35 draws silicon from melt 29 to produce a growth of silicon single crystal 31 as it is withdrawn. Crystal drive unit 49 rotates crystal 31 at a reference rate as it pulls crystal 31 from melt 29. Crucible drive unit 45 similarly rotates crucible 19 at another reference rate in either the opposite direction (counter-rotation) or in the same direction (i.e., iso-rotation) relative to crystal 31. A control unit 51 of FIG. 1 initially controls the withdrawal rate and the power that power supply 27 provides to heater 21 to cause a neck down of crystal 31. Typically, crystal growth apparatus I 3 grows the crystal neck at a substantially constant diameter as seed crystal 35 is drawn from melt 29. For example, the control unit 51 maintains a substantially constant neck diameter of about five percent of the desired body diameter. After the neck reaches a desired length, control unit 51 then adjusts the rotation, pull rate, and/or heating parameters to cause the diameter of crystal 31 to increase in a cone-shaped manner until a desired crystal body diameter is reached. For example, the control unit 51 decreases the pull rate to create an outwardly flaring region typically referred to as the taper of the crystal. Once the desired crystal diameter is reached, control unit 51 controls the growth parameters to maintain a relatively constant diameter as measured by apparatus 11 until the process approaches its end. At that point, the pull rate and heating are usually increased for decreasing the diameter to form a tapered portion at the end of single crystal 31. The control unit 51 is further configured to control the process parameters that affect the shape of the melt-solid interface to achieve a target melt-solid shape profile as a function of crystal length. By controlling the melt-solid interface shape according to a target melt-solid shape profile as a function of axial length, a region substantially free of undesirable amounts or sizes of agglomerated defects may be formed in the crystal. Further, by selecting a smooth seed lift profile that is determined using the V/I transition pull rate values, perfect silicon material may be produced over substantially all of the crystal body length.

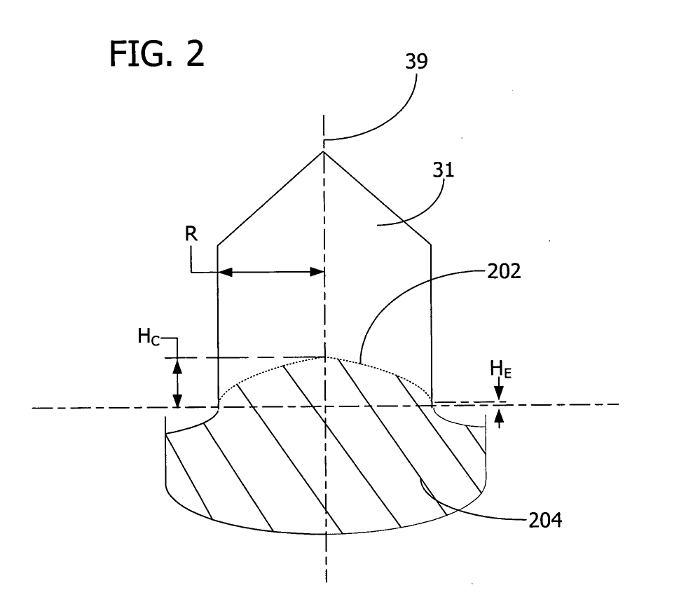

Referring now to FIG. 2, there is shown a growing single silicon crystal 31 having a radius R, a concave melt-solid interface 202 relative to the crystal 31, and molten silicon melt 204. The growing crystal 31 has a height in the center from the melt surface Hc, and has a height from the edge to the melt surface He. He is typically not zero because as the crystal is grown and being pulled away from the melt surface, the crystal 31 is actually pulled up slightly away from the actual melt surface, which results in the edge of the growing crystal 31 being slightly above the level of molten silicon in the melt. Although, the molten silicon/silicon crystal interface 202 is shown as having a concave shape, the shape of the interface 202 may change during body growth from, for example, from concave to convex, or from convex to concave, or from concave to flat to convex etc. It should also be noted that the terms convex and concave refer to the position of the melt-solid interface at the axis of the crystal relative to the melt-solid interface at the edge of the crystal. In this regard, the melt solid interface shape may be convex to the crystal for a portion of the radius and concave to the crystal for another portion of the radius forming a “gull-wing” shape as discussed earlier. In such cases, the “gull-wing” shape is said to be concave to the crystal when the melt-solid interface at the axis of the crystal is higher than the melt-solid interface at the edge of the crystal and is said to be convex to the crystal when the melt-solid interface at the axis of the crystal is lower than the melt-solid interface at the edge of the crystal.

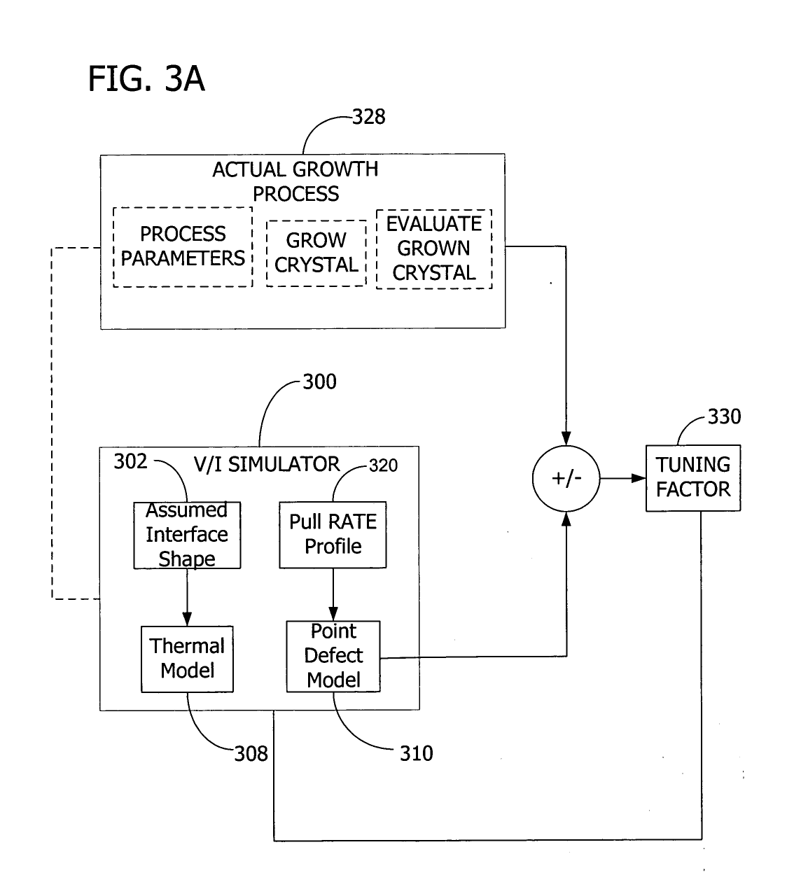

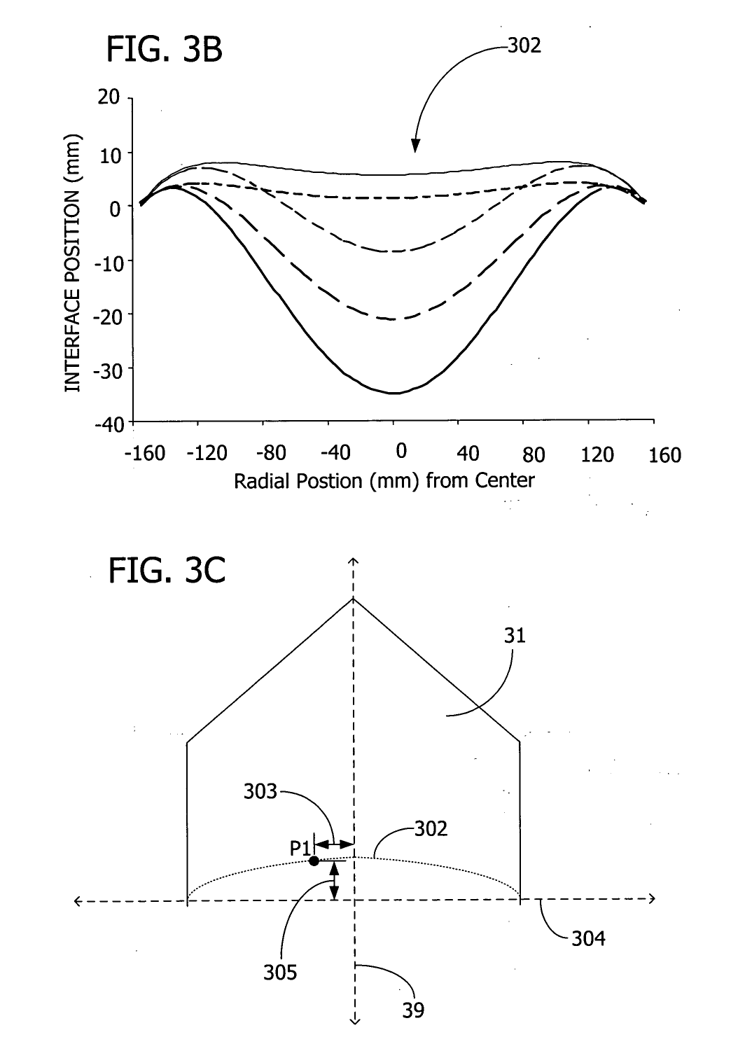

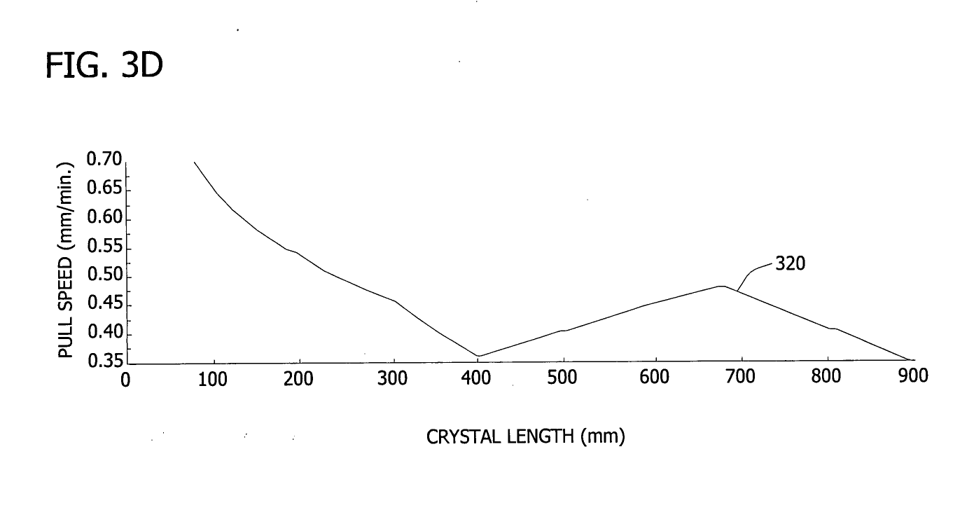

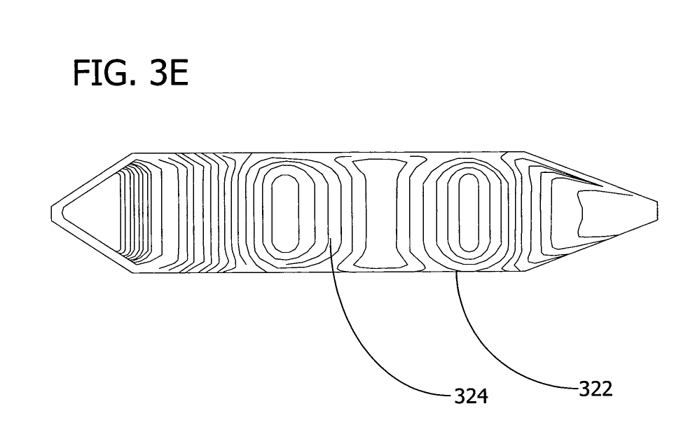

Referring now to FIG. 3A, modeling components of a V/I simulator 300 are shown. The V/I simulator is used for generating an expected V/I transition occurring at a particular location in a growing crystal as a function of a given melt-solid interface shape associated with the particular location. In accordance with one embodiment of the invention, various molten silicon/silicon crystal interface shapes 302 are assumed (see FIG. 3B) and each assumed shape 302 is analyzed by the V/I simulator 300 to identify an target melt-solid interface shape that produces a substantially flat V/I transition when the growth parameters have been selected such that the simulated ingot transitions from vacancy dominated to interstitial dominated. As described above, it has been discovered that a substantially flat V/I transition corresponds to a region of the crystal substantially free of undesirable amounts or sizes of agglomerated defects. Each molten silicon/silicon crystal shape is represented, for example, by a series of data points each having a horizontal component x and vertical component y. Referring briefly to FIG. 3C, the horizontal component x is representative of the horizontal distance, as indicated by reference character 303, between the same point P1 and the common axis of symmetry 39. The vertical component y is representative of the vertical distance, as indicated by reference character 305, between a point PI on the assumed molten silicon/silicon crystal interface shape 302 and a radial axis 304 perpendicular to the common axis of symmetry 39 at an axial position along the length of the crystal 31 (e.g., 100 mm, 200 mm, 300 mm, etc.) that corresponds to the interface at the peripheral edge. The series of data points associated with a particular assumed interface shape 302 are entered into the defect model or defect simulator along with the surface temperature calculated by a thermal model 308 to generate a corresponding temperature gradient G (temperature field) wherein the growth parameters have been selected such that the simulated ingot transitions from vacancy dominated to interstitial dominated. The thermal model 308 is for example a finite element based commercial software such as MSC.MARC™ available from MSC Software Corporation located in Santa Ana, Calif., and modified to include radiative heat transfer in the method published by Virzi.

In one embodiment, the defect model is a dynamic defect modeler 310 linked to the thermal model 308, and generates a point defect profile for an ingot being pulled from silicon 31 melt according to a predetermined pull rate profile 320. The defect model 310 may be either a point defect modeler or an agglomerated point defect modeler. One commercially available steady state point defect model interfaces with the software package CrysVUn available from the Fraunhofer Institute for Integrated Circuits located in Erlangen, Germany. An unsteady state point defect simulator has been published by Brown et al. (Journal of crystal Growth, 2001).In this case, the predetermined pull rate is representative of a ramped pull rate that forces the ingot to transition from vacancy dominated to interstitial dominated, and hence generate a V/I transition profile (i.e., point defect profile).

Referring briefly to FIG. 3D, an exemplary velocity profile 320 for causing V/I transitions during simulated growth is shown. As can be seen, the crystal pulling speed is ramped up and down to reveal both interstitial associated defects and vacancy associated defects in the grown crystal. Referring briefly to FIG. 3E, an exemplary V/I transition plot 322 generated by the V/I simulator 300 in response to an assumed melt-solid interface shape 302 is shown. The V/I transition plot 322 shows expected VI transition profiles, as indicated by reference character 324, at various axial positions along the crystal. As discussed above, a substantially flat V/I transition profile is indicative of a target melt-solid interface shape and target pull rate capable of producing silicon that is substantially free of relatively large or otherwise undesirable agglomerated defects in the crystal puller and at the axial position being simulated. In contrast, a V/I transition that is substantial non-flat is indicative of a melt-solid interface shape more likely to result in the formation of micro defects (e.g. agglomerated point defects and oxygen precipitates) in a portion or all of the ingot at the selected axial position. Thus, by using the V/I simulator 300 to identify a target melt-solid interface shape and target pull rate that produce a substantially flat V/I transition for each of the plurality of axial positions, a target melt-solid interface shape profile and target pull rate profile can be defined and process parameters may then be estimated stored in a memory. In one embodiment, a target melt-solid interface shape profile and a target pull rate profile may be determined for at least 2 axial positions. In other embodiments the target melt-solid interface shape profile and a target pull rate profile may be determined for at least 4 axial positions, for at least 8 axial positions and may even be determined for at least 12 axial positions or more without departing from the scope of the present invention.

In another embodiment, the defect model is a static agglomerated defect modeler such as developed at the Massachusetts Institute of Technology Cambridge, Mass. and described in “Modeling the Linkages between Heat Transfer and Microdefect Formation in Crystal Growth: Examples of Czochralski Growth of Silicon and Vertical Bridgrnan Growth of Bismuth Germanate,” T. Mori, Ph. D. Thesis, Massachusetts Institute of Technology, 2000.

In the case of a static agglomerated defect model, both pull rate and the melt-solid interface shape may be analyzed by the V/I simulator to identify target melt-solid interface shapes and target pull rates at each of the various axial positions.

Moreover, the V/I simulator 300 can be fine tuned by growing a crystal 31 according to the defined profiles and comparing simulated V/I transitions to actual V/I transitions in a grown crystal 31 grown in an actual growth process 328 to determine a tuning factor 330. For example, by logging actual operating parameters during the actual growth process, and evaluating actual V/I transitions in the grown crystal the model can be fine tuned to improve the accuracy of predicted V/I transitions. In one embodiment, copper decoration and secco etching processes are used to reveal the actual V/I transitions crystal. Furthermore, actual interface shape measurements may be taken from test crystals by axial cutting of full-width thin samples, fully precipitating the oxygen in these samples, etching to remove the denuded zone and to clean the surface, and decorative etching to show the precipitation variation at the as grown solid-liquid interface. Based on actual transition seed lift values identified in grown crystals using metallic thermal precipitation of microdefects and subsequent decorative etching methods, a smooth seed lift profile may then be defined to achieve perfect silicon production over a majority of the crystal body length.

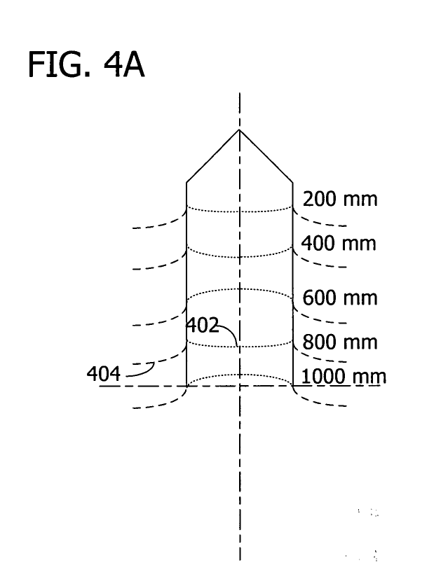

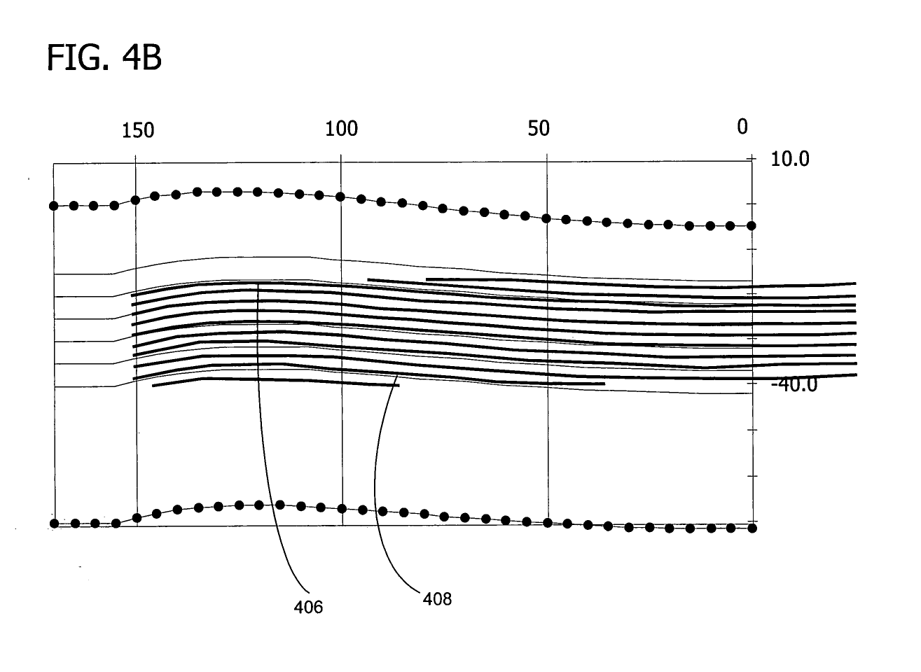

Referring now to FIG. 4A, various melt-solid interface shapes corresponding to an exemplary melt-solid interface shape profile for growing a single crystal silicon ingot 31 substantially free of, for example, undesirably large agglomerated defects are shown. The profile defines a particular target melt-solid interface shape for each of a plurality of axial position along the length of the crystal 31. In this case, melt-solid interface shape profile defines target melt-solid interface shapes for a crystal at 200 mm intervals along the length of the crystal (i.e., 200 mm, 400 mm, 600mm, etc.). For example, the target molten silicon/silicon crystal interface shape at an axial position located 800 mm from the seed end is illustrated by line 402 and the corresponding melt level is indicated by line 404. Notably, each of the shapes in the profile is represented by a series of data points such as described above in reference to FIG. 3B. The actual melt-solid interface is determined post crystal growth. For example, a vertical section 406 of the ingot is cropped and subjected to a precipitation thermal cycle (See FIG. 4B). The section 405 is then imaged using a lifetime map. This image decorates the interface shape, as indicated by reference character 408 as illustrated in FIG. 4B. Thereafter interface is then measured and compared to the baseline profile (i.e., melt-solid interface shape profile).

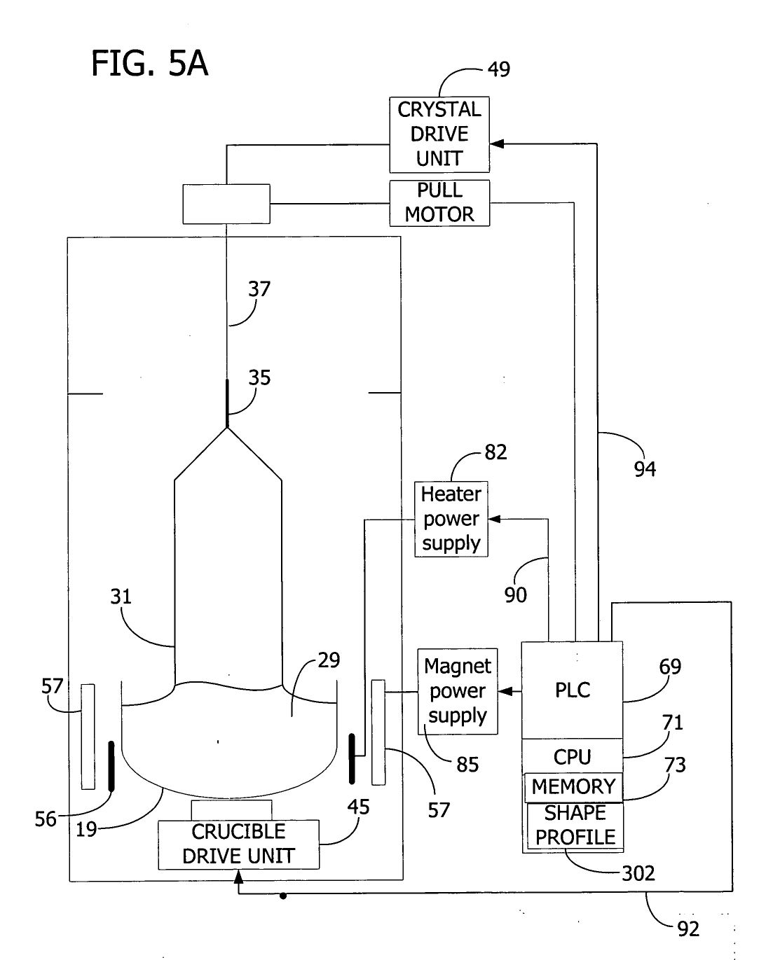

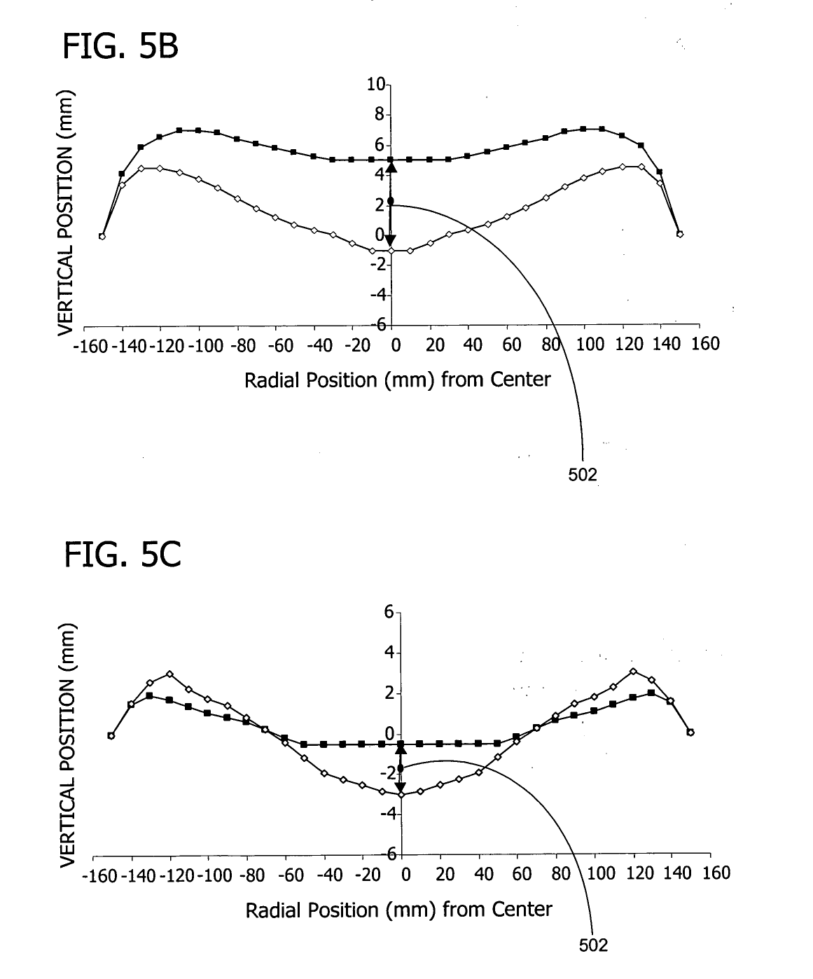

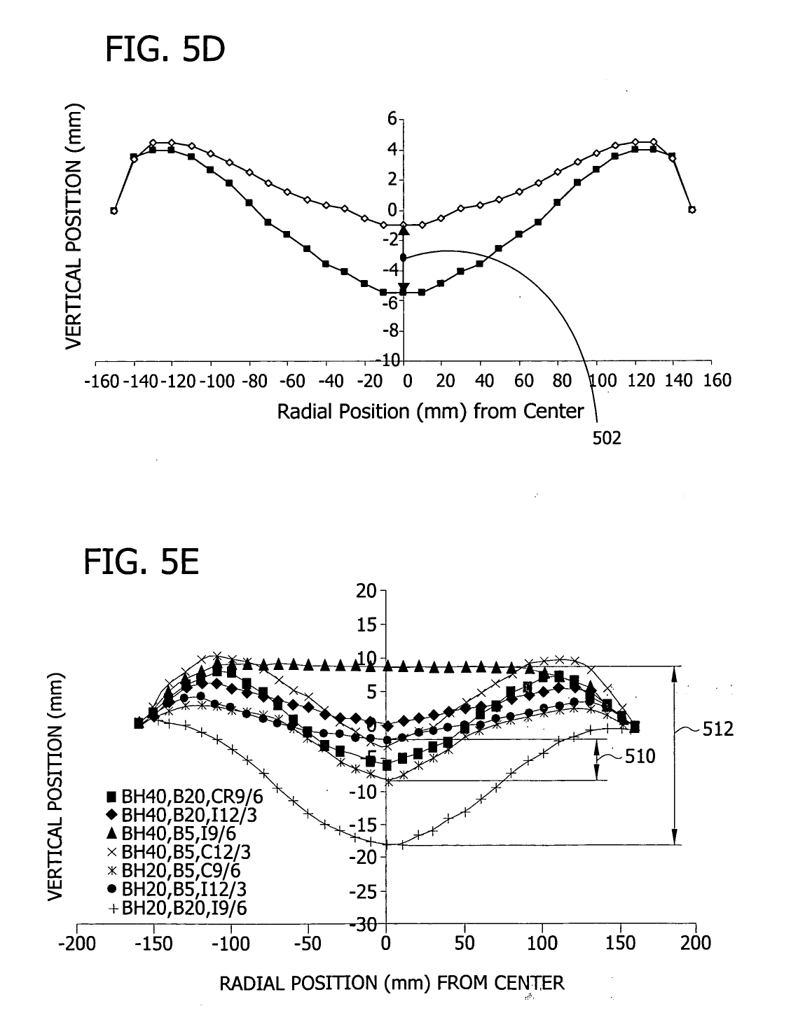

Referring next to FIG. 5A, the components of system 11 for controlling the melt-solid interface shape of a crystal according to one preferred embodiment of the invention are shown. A programmable logic controller (PLC) 69 having a central processing unit (CPU) 71 and a memory 73 is connected to output devices such crucible drive unit 45, bottom heater supply 82, crystal drive unit 49, and magnet power supply 85 for controlling the melt-solid interface shape. In this embodiment, the memory 73 stores target operating parameters required to achieve a target melt-solid interface shapes at particular axial position as defined by the melt-solid interface shape profile 302. For example, memory includes a target pull velocity, a target temperature of the melt, a target magnetic field, a target rotational speed of the ingot, a target rotational direction of the ingot, a target rotational speed of the crucible; and/or a rotational direction of the crucible. The CPU 71 and PLC 69 are responsive to the stored target parameters to adjust an operating condition of the crystal growing apparatus 13 such as heat flux to establish the desired a temperature field in the melt, a magnetic field within the crucible, a rotational speed of the ingot, a rotational direction of the ingot, a rotational speed of the crucible; and/or a rotational direction of the crucible. Such operating conditions are adjusted by adjusting the power being supplied to one or more output devices in order to achieve the targets shape at the various axial positions along the length of the crystal. For example, the CPU 71 determines a current length of the ingot from, for example, position sensors (not shown) of the crystal growing apparatus, and, thus a current axial position. The CPU 71 calculates a difference between process parameters that will establish a first target shape (e.g., height ratio) corresponding to a current position (e.g., 100 mm) along the crystal, and a second set of process parameters that will establish a second target shape corresponding to a next position (e.g. 200 mm) along the crystal to determine a set of operating parameter set points. Operating parameter set points may include, for example, a heater power set point for a heater power supply 82, a magnet power set point for a magnet power supply 85, a crucible rotational speed set point for a crucible drive unit 45, and a crystal rotational speed set point for the crystal drive unit 49. The PLC 69 is responsive to the an operating parameter set point to generate a control signal to adjust the one or more output devices affecting one or more operating conditions of the crystal growing apparatus.

In one embodiment, the CPU 71 is responsive to the desired melt-solid interface shape profile 302 and the determined length by the storage of a desired heater power set point or profile. The PLC 69 is responsive to the heater power set point to generate a heater control signal 90 to supply to the heater power supply 82. The heater power supply 82 is responsive to the heater control signal 90 to control the current being supplied to the bottom heater 56 (e.g., resistance heater 21) surrounding the crucible 19 to control the temperature of the melt. More specifically, the heater control signal 90 controls the power being supplied to bottom heater 56 to control the temperature of the melt and a temperature profile along the crucible wall, and, thus, control the melt-solid interface shape. It has been discovered that the height of the interface increases with the heat flux from the bottom heater 56. As a result, a desired change in center height, as indicated by 502, of the interface height can be achieved by increasing power supplied to the bottom heater 56 by an amount that yields the desired change in height. For example, increasing the power to the bottom heater by 10 kilowatts, increases the height of the interface shape approximately 6 mm in a 28″ crucible, in a chosen hotzone configuration. (See FIG. 5B). In other words, a higher bottom heater temperature results in an increase in the height of the interface shape. The range of operation is controlled by requirements of the desired interface shape and other quality parameters, such as oxygen concentration. The estimated gain in interface height with respect to the change in heater power, is GBH=0.6 mm/kW. Notably, changing the lower or side insulation in a hotzone can also achieve the desired temperature condition, and thus, influence the melt-solid interface shape. In one embodiment, the crystal growing apparatus includes a primary heater and a secondary heater. The primary heater is for example a side heater (not shown) and provides diameter control adjustment. The secondary heater is, for example, bottom heater 56 and provides melt gradient and interface shape control. That is, the secondary heater is adjusted according to the heater power set point to change the temperature gradient of the melt to control shape of melt-solid interface.

In another embodiment, the CPU 71 is responsive to the desired melt-solid interface shape profile 302 and the determined length by the storage of a determined magnet power set point. The PLC 69 is responsive to the magnet power set point to generate a magnet control signal 92 to supply to the magnet power supply 85. The magnet power supply 85 is responsive to the magnet control signal 92 to control the current being supplied to coils of a magnet 57 surrounding the crucible 19 to control the magnet field being applied to the melt 29. In particular, the application of a magnetic field provides a means of controlling the melt-solid interface shape along with the oxygen concentration. It has been discovered that by, decreasing the magnetic field strength, the melt-solid interface height increases. As a result, increasing, or decreasing, the power supplied to the magnet by an amount that yields the desired change in the magnetic field can achieve a desired change in center height 502 of the interface. For example, decreasing the magnetic field fifteen percent (15%) by decreasing the current, and thus power, to the magnet, increases the center height 502 of the interface shape approximately 2.5 mm. (See FIG. 5C). Thus, the estimated gain in interface height with respect to the change in field strength, is G_{B}=−0.167 mm/%. The magnet intensity is defined in relative units of field strength for a particular hot zone process. In this case, a value of 100% cusp magnetic field corresponds to 1000 G axial field at the bottom center of a 200 mm deep melt, with zero axial field at the top center of the melt. The maximum current is 750 Amps per coil

In one embodiment, the CPU is responsive to the desired melt-solid interface shape profile 302 and the determined length by the storage of a determined crucible rotational speed set point and crystal rotational speed set point. The PLC 69 is responsive to linearly compute intermediate crucible rotational speed set point and the crystal rotational speed set points, based on the target values at selected crystal lengths to generate a crucible rotation control signal 94 and crystal rotation control signal 94 to supply to the crucible drive unit 45 and crystal drive unit 49, respectively. As a result, the relative rotational rate, or delta rotation, between the crucible 19 and crystal 31 is controlled to control the interface shape. Where the relative rotation rate refers to the absolute difference between the absolute crystal rotation rate and absolute crucible rotation rate, (i.e., ∥seed rotation−|crucible rotations. It has been discovered that, an increase in delta rotation increases the interface height; while a decrease in delta rotation decreases the interface height 502. As a result, a desired change in the center height of the interface height can be achieved by controlling the rotational speed differential between the crystal and the crucible. For example, increasing the rotational speed differential by two (2) revolutions per minute, increases the center height 502 of the interface shape approximately 4.5 mm. (See FIG. 5D) The magnitude of the change is a function of absolute rotation rates of crystal and crucible. The estimated gain in interface height with respect to the change in delta rotation, is G_{Rot}=2.25 mm/rpm. In this instance, both the crucible 19 and crystal 31 are rotated in the same direction; iso rotation.

In another embodiment, the crucible 19 is rotated in one direction and the crystal 31 is rotated in the same direction to improve the range over which the melt-solid interface shape can be controlled. FIG. 5E illustrates exemplary ranges over which the melt-solid interface shape can be controlled during and counter rotation and iso-rotation processes as indicated by double arrows 510, 512, respectively. As described above, an important parameter for controlling the melt-solid interface shape is the convection path of the molten silicon melt 29 within the crucible 19. The convection path is driven by the forced convection due to the rotations of the crucible and the crystal. Moreover, the effect of Iso-rotation coupled with various process conditions has shown to provide an increase in the melt-solid interface operating range. In other words, the range over which the interface shapes can be increases dramatically. The absolute changes in interface shape and height are functions of hotzone, process parameters, and axial position of crystal. The interface height is defined as the vertical distance between the edge of the crystal and the center of the crystal. For the experimental hotzone, the range over which the interface height could be controlled increased by 356%, from 5.5 mm to 25.25 mm. Thus the change to Iso-rotation provides an improved dynamic range to increase or decrease the axial gradient at the interface.

Although the invention is described above in reference to controlling various parameters individually, the present invention includes controlling two or more of the parameters to achieve the desired melt-solid interface shape.

As described above in reference to FIG. 3A, the V/I simulator 300 can be fine tuned by growing a crystal 31 according to the defined profile and comparing simulated V/I transitions to actual V/I transitions in the grown crystal 31. In other words, the V/I simulator and control components of system 11 (i.e., PLC 69, CPU 71, memory 73) are used in combination to provide an open loop control system.

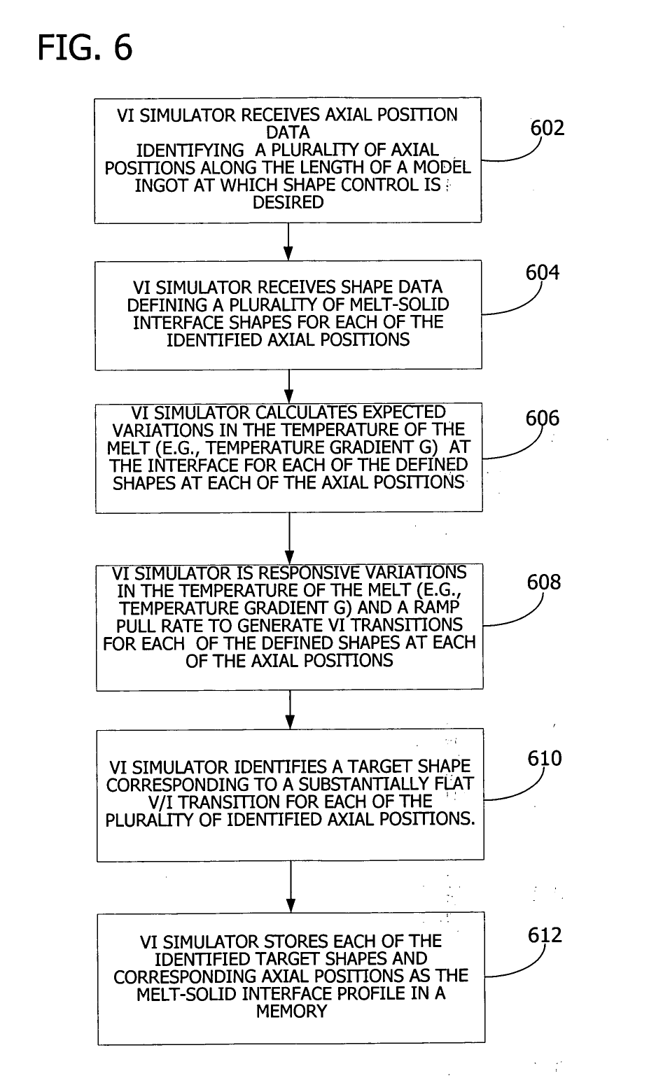

Referring now to FIG. 6, an exemplary flow chart illustrates a method for defining a melt-solid interface shape profile for use in combination with a crystal growing apparatus when growing a monocrystalline ingot according to the Czochralski process according to one embodiment of the invention. At 602, a V/I simulator 300 receives axial position data from an operator identifying a plurality of axial positions along the length of a model ingot at which shape control is desired. The V/I simulator 300 then receives shape data from the operator defining a plurality of melt-solid interface shapes for each of the identified axial positions at 604. At 606, the V/I simulator 300 is responsive to assumed processing parameters of the crystal growing apparatus (e.g., pull velocity, melt temperature, etc.), the identified axial positions and corresponding defined melt-solid interface shapes to define variations in the temperature of the melt at the interface. For example, the V/I simulator 300 calculates a temperature gradient G or across the interface or a temperature field in the crystal growing apparatus that corresponds to each of the defined melt-solid interface shapes. At 608, the V/I simulator 300 is responsive the calculated temperature gradient G to calculate the ratio between a defined velocity vₚ and the calculated temperature gradient G. In this case, the defined velocity vₚ corresponds to a velocity profile stored in a memory and defines a ramped pull rate. Strictly, the point defect concentration field in a crystal is determined by the simulator by solving the point defect dynamics in the calculated temperature field, without the explicit use of G profile. The two-dimensional diffusion effects are considered. The parameter v/G can be used as a reasonable indicator of the point defect distribution in the crystal, but it is not a fundamental property of silicon. Especially, near the edge of the crystal, the application of v/G rule is inaccurate. The point defect simulator, however, takes actual physics of point defect dynamics in determining the point defect concentration field. As describe above, during a dynamic growth process (i.e., varying v/G), point defects within the growing silicon crystal can change from being vacancy dominated to interstitial dominated, or vice versa, and there is an identifiable V/I transition associated with such a change. By using a ramped pull rate, the simulated ingot is forced to transition from vacancy dominated to interstitial dominated, and the V/I simulator 300 generates a V/I transition that corresponds to each of the defined melt-solid interface shapes for each of the identified axial positions at 610. At 612, the V/I simulator 300 identifies a target shape that corresponds to a substantially flat V/I transition for each of the plurality of identified axial positions. The V/I simulator 300 stores each of the identified target shapes and corresponding axial positions as the melt-solid interface profile in a memory.

In operation, a system for use in combination with a crystal growing apparatus for growing a monocrystalline ingot according to the Czochralski process has a memory storing a pre-computed set of process parameter setpoint values at various crystal lengths, that achieve or nearly achieve a desired melt-solid interface profile. The melt-solid interface profile represents a desired shape of a melt solid interface between the melt and the ingot during pulling as a function of a length of the ingot. A set of process gains allow estimation of operating parameters of the crystal growing apparatus as a function of the length of the ingot during pulling. Also, a controller is responsive to the determined operating parameter set point to adjust the operation condition of the crystal growing apparatus according to the determined operating parameter set point to control the shape of the melt-solid interface while the ingot is being pulled from the melt.

In defining the melt-solid interface shape profile, the process parameters may be selected based on actual oscillatory seed lift used to grow a crystal. In this instance, the actual interface shape may be confirmed, by a method of precipitation, bulk etching, and decorative etching or lifetime measurement. This embodiment of the present invention permits adjustment of the interface shape on subsequent crystals to closely achieve the desired interface shape at various crystal lengths. The seed lift profile may be changed from an oscillatory profile to a smooth profile based on the seed lift values experimentally determined where low or zero large-microdefect density is present (i.e., at the V/I transition boundary). The production of substantially radially-perfect or radially low defect silicon may be achieved, where small seed lift bias or profile adjustments are used to maintain low or zero large-microdefect levels, particularly where no interstitial loops or large vacancy clusters (as identified by D-defect or other measurements) occur.

### Appendix A

### Method of Defining Operating Window

The cooling rates through the temperature between 1150° C. and 800° C. determine the maximum possible acceptable operating window for the process, for a given V/I transition. The operating window is defined in terms of pull-rates. Suppose the mean pull-rate of a crystal at a location is x mm/min, a maximum operating window of y mm/min means that substantially large-microdefect free crystal at the chosen location can be produced within the pull-rate range between x+y/2 mm/min and x−y/2 mm/min. This is determined as follows.

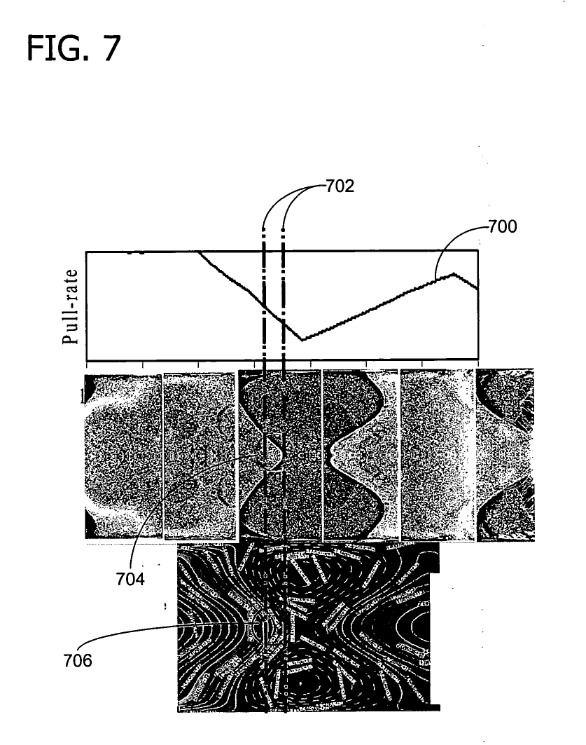

A crystal is grown with a varying pull-rate profile 700, as shown in FIG. 7, in a hot-zone with known cooling rates through the temperature range between 1150° C. and 800° C. It is then characterized to identify the substantially microdefect free region in the center, which is bracketed by the lines 702. Various characterization techniques such as FPD measurements can be applied. The actual interface shape of the crystal, as indicated by 704, near the substantially microdefect free region is measured. This interface shape is used to simulate the point defect distribution using the point defect simulator. The point defect simulator provides the excess point defect concentration field Cv-Ci as indicated by reference character 706, where Cv is the vacancy concentration and Ci is the interstitial concentration. A positive Cv-Ci indicates vacancy rich region; a negative Cv-Ci indicates interstitial rich region. Moreover, higher the Cv-Ci in a region, larger the vacancy-type microdefects formed; lower (but positive) the Cv-Ci in a region, the smaller the vacancy-type microdefects formed. If Cv-Ci is negative but higher in magnitude, larger interstitial-type microdefects are formed. Thus, for given cooling rates between 1150° C. and 800° C., there exists a region bracketed by positive Cv-Ci and a negative Cv-Ci, which is substantially large-microdefect free. This substantially large-microdefect free region can contain microdefects smaller than 30 nm in radius. This maximum operating window is determined by comparing the experimentally determined substantially microdefect free region and the Cv-Ci field predicted by the point defect simulator. This defines the maximum operating window for the given cooling rates.

Any circular disc cut from the shown cylindrical ingot at any axial location is still not completely substantially microdefect free. Since wafers produced from the ingot are circular discs, real operating window is defined by the width of the ingot that is substantially microdefect free everywhere along the radial location, i.e., from its center to the edge. This is called the real operating window. An acceptable interface shape for a given cooling rate can vary this real operating window. An acceptable interface shape giving an acceptable operating window of at least 0.005 mm/min, preferably 0.01 mm/min, and most preferably 0.02 mm/min or higher is determined first by the point defect simulator, and then by the actual crystal growth. Any interface allowing the production of substantially large-microdefect free circular discs is defined as acceptable.

1. A method for use in combination with a crystal growing apparatus for growing a monocrystalline ingot according to the Czochralski process, said crystal growing apparatus having a heated crucible containing a semiconductor melt from which the ingot is pulled, said ingot being grown on a seed crystal pulled from the melt, said method comprising the steps of:
determining a set point for an operating parameter of the crystal growing apparatus as a function of a length of the ingot during pulling, said set point being specified by a pre-defined melt-solid interface shape profile, said melt-solid interface shape profile representing a desired shape of a melt-solid interface between the melt and the ingot during pulling as a function of the length of the ingot and an operating condition affecting the melt; and
adjusting the operating condition of the crystal growing apparatus according to the determined operating parameter set point to control the shape of the melt-solid interface while the ingot is being pulled from the melt.

2. The method of claim 1 wherein the operating condition is one or more of the following:
temperature field of the melt;
magnetic field within the crucible;
rotational speed of the ingot;
rotational direction of the ingot;
rotational speed of the crucible; and
rotational direction of the crucible.

3. The method of claim 1 wherein the operating parameter set point is one or more of the following:
a heater power set point for a heater power supply of the crystal growing apparatus;
a magnet power set point for a magnet power supply of the crystal growing apparatus;
a crucible rotational speed set point for a crucible drive unit of the crystal growing apparatus; and
a crystal rotational speed set point for the crystal drive unit of the crystal growing apparatus.

4. The method of claim 3, wherein adjusting the operating condition according to the determined operating parameter set point includes adjusting power supplied to a heater of the crystal growing apparatus according to the heater power set point to change a temperature gradient of the melt to control shape of melt-solid interface.

5. The method of claim 3, wherein adjusting the operating condition according to the determined operating parameter set point includes adjusting power supplied to a magnet of the crystal growing apparatus according to the magnet power set point to change the convection of the melt to control the shape of melt-solid interface.

6. The method of claim 3, wherein adjusting the operating condition according to the determined operating parameter set point includes adjusting power supplied to the crucible drive unit of the crystal growing apparatus according to the crucible rotational speed set point and adjusting the power supplied to the crystal drive unit of the crystal growing apparatus according to the crystal rotational speed set point to change the convection of the melt to control the shape of melt-solid interface.

7. The method of claim 1, wherein the crucible and ingot are rotated in opposite directions to control the shape of melt-solid interface.

8. The method of claim 1, wherein the crucible and ingot are rotated in a same direction to control the shape of melt-solid interface.

9. The method of claim 1, wherein the set point for an operating parameter is determined for a selected hotzone of the crystal growing apparatus having a pre-computed crystal thermal boundary condition.

10. The method of claim 1 further comprising defining the melt-solid interface shape profile.

11. The method of claim 10, wherein defining the melt-solid interface shape profile includes:
selecting a plurality of axial positions along the length of a model ingot;
defining a plurality of melt-solid interface shapes for each of the identified axial positions;
determining a thermal model of a hotzone of the crystal growing apparatus for each of the axial positions and each of the melt-solid interface shapes;
defining a velocity profile representative of a ramped pull rate;
determining point defect model that captures a point defect concentration filed field in a region of the model ingot; said point defect model being responsive to the velocity profile and the thermal model for identifying a V/I transition for each of the plurality of defined melt solid interface shapes for each of the plurality of identified axial positions; and
identifying a target melt-solid interface shape corresponding to a substantially flat V/I transition for each of the plurality of identified axial positions.

12. The method of claim 11 further comprising storing each of the identified target shapes and corresponding axial positions in a melt-solid interface profile.

13. The method of claim 11, wherein defining a thermal model comprises defining an interface shape response model representative of a change in hotzone thermal characteristics.

14. A method for defining a melt-solid interface shape profile, said profile being used in combination with a crystal growing apparatus for growing a monocrystalline ingot according to the Czochralski process, said crystal growing apparatus having a heated crucible containing a semiconductor melt from which the ingot is pulled, said ingot being grown on a seed crystal pulled from the melt, and wherein said melt-solid interface shape profile represents a desired shape of a melt-solid interface between the melt and the ingot during pulling as a function of the length of the ingot, comprising
selecting a plurality of axial positions along the length of a model ingot;
defining a plurality of melt-solid interface shapes for each of the identified axial positions;
determining a thermal model of a hotzone of the crystal growing apparatus for each of the axial positions and each of the melt-solid interface shapes;
defining a velocity profile representative of a ramped pull rate;
determining a point defect model that captures a point defect concentration filed field in a region of the model ingot; said point defect model being responsive to the velocity profile and the thermal model for identifying a V/I transition for each of the plurality of defined melt solid interface shapes for each of the plurality of identified axial positions; and
identifying a target melt-solid interface shape corresponding to a substantially flat V/I transition for each of the plurality of identified axial positions.

15. A system for use in combination with a crystal growing apparatus for growing a monocrystalline ingot according to the Czochralski process, said crystal growing apparatus having a heated crucible containing a semiconductor melt from which the ingot is pulled, said ingot being grown on a seed crystal pulled from the melt, said apparatus comprising:
a memory storing a pre-defined melt-solid interface profile, said melt-solid interface profile representing a desired shape of a melt solid interface between the melt and the ingot during pulling as a function of a length of the ingot and an operating condition affecting the melt;
a processor responsive to the pre-defined melt-solid interface profile for determining a set point for an operating parameter of the crystal growing apparatus as a function of the length of the ingot during pulling; and
a controller responsive to the determined operating parameter set point to adjust the operation condition of the crystal growing apparatus according to the determined operating parameter set point to control the shape of the melt-solid interface while the ingot is being pulled from the melt.

16. The system of claim 15, wherein the operating condition is one or more of the following:
temperature of the melt;
magnetic field within the crucible
rotational speed of the ingot;
rotational direction of the ingot;
rotational speed of the crucible; and
rotational direction of the crucible.

17. The system of claim 15, wherein the determined operating parameter set point is one or more of the following:
a heater power set point for a heater power supply of the crystal growing apparatus;
a magnet power set point for a magnet power supply of the crystal growing apparatus;
a crucible rotational speed set point for a crucible drive unit of the crystal growing apparatus; and
a ingot rotational speed set point for a crystal drive unit of the crystal growing apparatus.

18. The system of claim 17, wherein the controller adjust one or more of the following to to control the shape of the melt-solid interface:
power supplied to a heater of the crystal growing apparatus according to the heater power set point to change a temperature gradient of the melt to control the shape of the melt-solid interface; and
power supplied to a magnet of the crystal growing apparatus according to the magnet power set point to change the convection of the melt to control the shape of the melt-solid interface.

19. The system of claim 15, wherein the controller adjust the power supplied to a crucible drive unit of the crystal growing apparatus according to the crucible rotational speed set point and adjust the power supplied to a crystal drive unit of the crystal growing apparatus according to the crystal rotational speed set point to change the convection of the melt to control the shape of the melt-solid interface.

20. The system of claim 15 further comprising a V/I simulator for pre-defining the melt-solid interface shape profile, and wherein the V/I simulator includes a temperature model for generating a temperature gradient for each of a plurality of melt-solid interface shapes at each pf a plurality of axial positions along the length of the crystal.
a velocity profile stored in a memory and defining a ramped pull rate;
a point defect model to responsive to the velocity profile and the temperature model to generate an expected V/I transition representative of the transition from an excess vacancy dominant region to an excess interstitial dominant region for each of the plurality of defined melt-solid interface shapes, wherein an operator examines the generated V/I transitions to identify a target shape corresponding to a substantially flat V/I transition for each of the plurality of identified axial positions for storage as a melt-solid interface profile in a memory.
